(19) United States
(12) Patent Application Publication
(10) Pub. No.: US 2024/0174889 A1
(43) Pub. Date: May 30, 2024

(54) ULTRAVIOLET-CURABLE COMPOSITION AND USE THEREOF

(71) Applicant: DOW TORAY CO., LTD., Shinagawa-ku, Tokyo (JP)

(72) Inventor: Takuya OGAWA, Ichihara-shi, Chiba (JP)

(21) Appl. No.: 18/283,292

(22) PCT Filed: Mar. 15, 2022
(86) PCT No.: PCT/JP2022/011666

§ 371 Date: Dec. 12, 2023

(30) Foreign Application Priority Data
Mar. 26, 2021 (JP) 2021-052575

(51) Int. Cl. C09D 183/08; C08G 77/00; C08G 77/04; C08G 77/14; H01B 3/46; H05K 5/03

(52) U.S. Cl. CPC C09D 183/08; C08G 77/045; C08G 77/14; H01B 3/46; C08G 77/70; H05K 5/03

(57) ABSTRACT

Provided is a UV curable composition containing a silicon atom, wherein a product obtained by curing the composition has excellent flexibility and excellent workability when applied to a substrate. The UV curable composition of the present disclosure comprises: (A) one or more organopolysiloxane with three or more silicon atoms and having, on average, two or more UV curable functional groups in a molecule; and (B) one or more organosilicon compound having one UV curable functional group in a molecule. The composition is substantially free or an organic solvent. In addition, the viscosity of the entire composition measured at 25° C. using an E-type viscometer is 80 mPa·s or less.

### TECHNICAL FIELD

The present invention relates to a UV curable composition curable by chemical rays (actinic rays), for example ultraviolet rays or electron beam, and in particular relates to UV curable compositions containing organosilicon compounds, preferably organosilanes and/or organopolysiloxanes, and in particular relates to UV curable compositions wherein cured products obtained therefrom have favorable mechanical properties, and particularly high elongation properties, and having excellent application properties. The curable composition of the present invention has excellent flexibility and is suitable as an insulating material for electronic and electrical devices, and particularly as a material for use as a coating layer and protective layer. Furthermore, the composition has excellent application properties and superior wettability to substrates, thus being useful as an inkjet printing material.

### BACKGROUND ART

Due to high heat resistance and excellent chemical stability, silicone resins have been used as coating agents, potting agents, insulating materials, and the like for electronic and electrical devices. Silicone resins include UV curable silicone compositions.

Touch panels are used in various display devices such as mobile devices, industrial equipment, car navigation systems, and the like. In order to improve detection sensitivity, electrical influence from light emitting sites such as light emitting diodes (LED) and organic light emitting devices (OLED) must be suppressed, and an insulating layer is usually placed between the light emitting part and the touchscreen.

On the other hand, thin display devices such as OLEDs have a structure in which a plurality of functional thin layers are stacked. In recent years, studies have been started to improve the overall reliability of display devices, particularly flexible display devices, by laminating an insulating layer with high flexibility onto the touchscreen layer. In addition, the inkjet printing method has been adopted as a processing method for organic layers to improve productivity. Therefore, a material that can be processed by the inkjet printing method is required for the aforementioned insulating layer.

International Patent Application Publication WO2019/117298 discloses a curable composition containing a disiloxane compound having a UV curable functional group, a polysiloxane having a UV curable functional group, and a silicon-free compound having a UV curable functional group optionally blended, and the curable composition being coatable by an inkjet method. However, due to the high ratio of the disiloxane compound having two or more UV curable functional groups in the composition, the hardness of a cured product thereof is high and may not be applicable to applications that require flexibility.

### RELATED ART DOCUMENTS

### Patent Documents

Patent Document 1: WO2019/117298

### SUMMARY OF THE INVENTION

### Problem to be Solved by the Invention

As described above, UV curable organopolysiloxane compositions are well known, but there is still a need for UV curable compositions in which a cured product thereof has excellent flexibility and has excellent workability, particularly low viscosity, for application to substrates. The present invention attempts to provide a curable composition containing a silicon atom, in which a product obtained by curing has both high flexibility, particularly high elongation properties, and excellent workability when applied to a substrate, and in particular, a UV curable composition.

### Means for Solving the Problem

The present invention was completed by the discovery that a UV curable composition, which is obtained by combining (A) one or more organopolysiloxanes having three or more silicon atoms and, on average, two or more UV curable functional groups in a molecule, and (B) one or more organosilicon compounds having one UV curable functional group in a molecule, has low viscosity and excellent workability when applied to a substrate, and a cured product thereof exhibits excellent flexibility.

The present invention relates to a UV curable composition containing an organosilicon compound, particularly a UV curable organopolysiloxane composition, and the composition is cured by forming a bond by a UV curable functional group. However, the curing method is not limited to UV irradiation, and an arbitrary method in which a UV curable functional group can cause a curing reaction can be used. For example, electron beam irradiation may be used to cure the composition of the present invention.

A UV curable composition of the present invention contains: (A) one or more organopolysiloxane with three or more silicon atoms and having, on average, two or more UV curable functional group in a molecule; and (B) one or more organosilicon compound having one UV curable functional group in a molecule, wherein the viscosity of the entire composition measured at 25° C. using an E-type viscometer is 80 mPa·s or less. Moreover, the composition is free of an organic solvent, and cured product when the composition is cured has favorable flexibility. Note that unless otherwise specified herein, the viscosity of a substance is the value measured using an E-type viscometer at 25° C.

The UV curable functional group of component (A) of the present invention is preferably a cationic polymerizable reactive group. Furthermore, the cationic polymerizable reactive group is preferably an epoxy group-containing group.

The average number of silicon atoms in the aforementioned component (A) is preferably 10 or less.

The aforementioned component (B) is preferably an organosilicon compound selected from a group consisting of linear, branched, and cyclic organosilanes and organopolysiloxanes expressed by the average compositional formula:

R_{c}R′_{d}SiO_{(4-c-d)/2} (2)

where R represents a UV curable functional group; R′ represents a group selected from monovalent hydrocarbon groups, hydroxyl groups, and alkoxy groups excluding the UV curable functional group; c and d are numbers that satisfy the following conditions: 1<c+d≤4 and 0.05≤c/(c+d)≤0.25, and the number of R in the molecule is 1.

The aforementioned component (A) is preferably a linear, branched or cyclic organopolysiloxane expressed by the average compositional formula:

RₐR′_{b}SiO_{(4-a-b)/2} (1)

where R represents a UV curable functional group; R′ represents a group selected from monovalent hydrocarbon groups, hydroxyl groups, and alkoxy groups excluding the UV curable functional group; and a and b are numbers that satisfy the following conditions: 1≤a+b≤3 and 0.01≤a/(a+b)≤0.5, and at least two Rs are present in a molecule.).

The organosilicon compound of component (B) is preferably a silicon-containing compound containing one UV curable functional group in a molecule, the silicon-containing compound selected from a group consisting of:

organopolysiloxanes expressed by the following formula (3′):

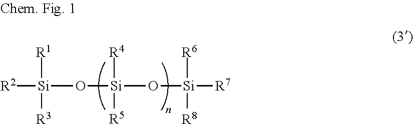

where of all R¹ to R⁸ groups, only one UV curable functional group is present in a molecule; the other groups of R¹ to R⁸ independently represent an unsubstituted or fluorine-substituted monovalent hydrocarbon group; and n is a numerical value of 0 or more and 3 or less; cyclic organopolysiloxanes expressed by the following formula (4′):

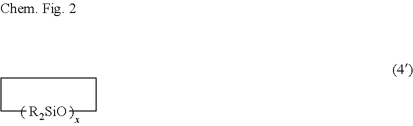

where R independently represents a group selected from UV curable functional groups and unsubstituted or fluorine-substituted monovalent hydrocarbon groups, x is an integer of 3 to 5, and only one UV curable functional group is present in a molecule; and organosilanes expressed by the following formula (5′):

RSiR′₃ (5′)

where R represents a UV curable functional group, and R′ represents a group selected from monovalent hydrocarbon groups, hydroxyl groups, and alkoxy groups excluding the UV curable functional group.

The aforementioned component (B) is preferably an organopolysiloxane having three or more silicon atoms and having one UV curable functional group in a molecule.

Furthermore, the aforementioned component (A) is preferably at least one type of organopolysiloxane having a UV curable functional group, selected from a group consisting of:

organopolysiloxanes expressed by the following formula (3):

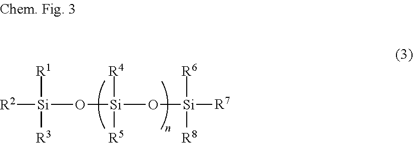

where two or more, on average, of all R¹ to R⁸ groups per molecule are UV curable functional groups; other R¹ to R⁸ independently represent an unsubstituted or fluorine-substituted monovalent hydrocarbon group; and n is a number of 1 or more and 20 or less; organopolysiloxanes expressed by the average unit formula:

(R₃SiO_{1/2})ₑ(R₂SiO_{2/2})_{f}(RSiO_{3/2})_{g}(SiO_{4/2})ₕ (5)

where R independently represents a group selected from UV curable functional groups and unsubstituted or fluorine-substituted monovalent hydrocarbon groups, at least two of all Rs are UV curable functional groups, (g+h) is a positive number, e is 0 or a positive number, and f is a number within a range of 0 to 10.);
cyclic organopolysiloxanes expressed by the following formula (4):

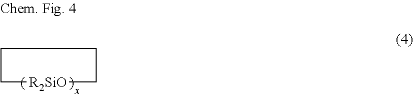

where R independently represents a group selected from UV curable functional groups and unsubstituted or fluorine-substituted monovalent hydrocarbon groups, x is an integer of 3 to 10, and at least two UV curable functional groups are present in a molecule); and mixtures of two or more organopolysiloxane optionally selected therefrom.

The number of UV curable functional groups in the aforementioned component (A) is preferably two per molecule on average.

The aforementioned component (A) is preferably a linear organopolysiloxane having UV curable functional groups at both ends and an average number of silicon atoms of 5 or more and 12 or less.

Component (B) with component (A) in the curable composition is preferably included at a mass ratio of 25/75 to 90/10 (A/B), or the amount of component (A) preferably exceeds 20 mass % of the total amount of the curable composition.

In one preferred aspect of the UV curable composition of the present invention, the composition further contains at least one (A′) organopolysiloxane having two silicon atoms and having two UV curable functional groups in a molecule at an amount such that the mass ratio of component (A′) with respect to the total of component (A), component (B) and component (A′) is less than 30%.

In one preferred aspect of the present invention, component (B) is 1,1,1,3,5,5,5-heptamethyl-3-[2-(3,4-epoxycyclohexyl)ethyl]trisiloxane.

In one preferred aspect of the present invention, component (A) is 1,1,3,3,5,5,7,7,9,9-decamethyl-1,9-bis[2-(3,4-epoxycyclohexyl)ethyl]pentasiloxane.

The viscosity of the UV curable composition of the present invention, measured at 25° C. using an E-type viscometer, is particularly preferably in a range of 5 to 30 mPa·s.

The present invention further provides an insulating coating agent containing the aforementioned UV curable composition. The UV curable composition of the present invention is useful as an insulating coating agent.

The present invention further provides a cured product of the aforementioned UV curable composition. Furthermore, the present invention also provides a method of using the cured product as an insulating coating layer.

The present invention further provides a display device such as a liquid crystal display, organic EL display, or organic EL flexible display that include a layer containing a cured product of the aforementioned UV curable composition.

### DESCRIPTION OF THE PREFERRED EMBODIMENTS

A configuration of the present invention will be further described in detail below. The UV curable composition of the present invention contains, as curable essential components, (A) one or more organopolysiloxane with three or more silicon atoms and having, on average, two or more UV curable functional group in a molecule and (B) one or more organosilicon compound having one UV curable functional group in a molecule, and, if necessary, can contain a component selected from photocationic polymerization initiators and various additives. However, the curable composition of the present invention is characterized by substantially not containing organic solvent.

In the present specification, the term “organosilicon compound” is used as a term to refer to a concept that includes organosilanes, organosiloxane oligomers, and organopolysiloxanes.

In the present specification, the term “polysiloxane” refers to a siloxane unit (Si—O) with a degree of polymerization of two or more, in other words with an average of two or more Si—O bonds per molecule. Polysiloxanes include siloxane oligomers such as disiloxanes, trisiloxanes, tetrasiloxanes, and the like, as well as siloxane polymers with higher degrees of polymerization.

Component (A)

Component (A) is one or more organopolysiloxanes with three or more silicon atoms and having, on average, two or more UV curable functional groups in a molecule. A molecular structure thereof can be arbitrary so long as the objective can be achieved. In particular, the UV curable functional group of component (A) is particularly preferably a cationic polymerizable functional group, and more preferably an epoxy group-containing group.

The viscosity of component (A) at 25° C. is preferably 1 to 1000 mPa·s, more preferably 1 to 500 mPa·s, particularly preferably 1 to 100 mPa·s, and most preferably 1 to 50 mPa·s.

Furthermore, component (A) contains 3 to 20 silicon atoms per molecule, and preferably in a range of 3 to 12.

The polysiloxane of component (A) is an organopolysiloxane that is a linear, branched, or cyclic, preferably linear or branched, and particularly preferably linear organopolysiloxane, expressed by the following average compositional formula:

RₐR′_{b}SiO_{(4-a-b)/2} (1.

In formula (1),

R represents a UV curable functional group;
R′ represents a group selected from monovalent hydrocarbon groups, hydroxyl groups, and alkoxy groups excluding the UV curable functional group; and
a and b are numbers that satisfy the following conditions: 1≤a+b≤3 and 0.01≤a/(a+b)≤0.5, and preferably 2≤a+b≤3 and 0.05≤a/(a+b)≤0.34.

The UV curable functional group represented by R in formula (1) is an organic group capable of generating a bond between each other by UV irradiation in the presence or absence of a photoinitiator. Examples of the UV curable functional groups can include radical polymerizable groups and cationic polymerizable groups. Radical polymerizable groups are not particularly limited so long as they are a functional group that can form a new bond by a radical reaction mechanism, and particularly a bond between radical polymerizable groups. Examples can include acrylic groups, methacrylic groups, maleimide groups, and organic groups containing any of these groups. Specific examples of the radical polymerizable group include groups such as acryloxypropyl, methacryloxypropyl, acrylamidopropyl, methacrylamidopropyl, 3-(N-maleimido)propyl, and the like. Examples of cationic polymerizable groups include vinyl ether groups, epoxy group-containing groups, oxetane group-containing groups, and other groups, such as CH₂═CH—O—(CH₂)ₙ— where n is an integer from 3 to 20), glycidyloxy —(CH₂)ₙ— where n is an integer from 3 to 20), 3,4-epoxycyclohexyl —(CH₂)ₙ— where n is an integer from 2 to 20), and the like.

The UV curable functional group is preferably an epoxy group-containing group. Examples of particularly preferable groups include glycidyloxypropyl groups, epoxycyclohexylalkyl groups, and particularly a 3,4-epoxycyclohexylethyl group. Linear, branched, or cyclic organopolysiloxanes expressed by the average compositional formula above have at least two UV curable functional groups (R) on average per molecule. The number of UV curable groups is preferably 2 to 6, more preferably 2 to 4, particularly preferably 2 to 3, and most preferably 2 per molecule on average.

R′ represents a monovalent hydrocarbon group, which includes unsubstituted monovalent hydrocarbon groups and fluorine-substituted monovalent hydrocarbon groups. The unsubstituted or fluorine-substituted monovalent hydrocarbon group is preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, octyl, and other groups, and methyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups. The 3,3,3-trifluoropropyl group is preferred as the fluorine-substituted monovalent hydrocarbon group.

The organopolysiloxane expressed by formula (1) has a viscosity at 25° C. of 1 to 1000 mPa·s, 1 to 500 mPa·s, or 1 to 100 mPa·s, but most preferably 1 to 50 mPa·s. The viscosity of the organopolysiloxane can be adjusted by changing the ratio of a and b in formula (1) as well as the molecular weight.

The organopolysiloxane expressed by formula (1) preferably has on average 3 to 20 silicon atoms per molecule, more preferably 3 to 12 atoms, and even more preferably 5 to 12 atoms.

In one preferred aspect, the organopolysiloxane of component (A) is a compound expressed by the following formula (3):

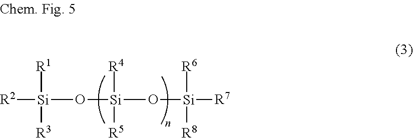

Similar to the compound expressed by formula (1) above, the organopolysiloxane expressed by formula (3) has on average two or more UV curable functional groups per molecule. In formula (3), of all R¹ to R⁸ groups, an average of two or more per molecule are UV curable functional groups. The UV curable functional group is an organic group capable of generating a bond between each other by UV irradiation in the presence or absence of a photoinitiator. Examples of the UV curable functional groups can include radical polymerizable groups and cationic polymerizable groups. Radical polymerizable groups are not particularly limited so long as they are a functional group that can form a new bond by a radical reaction mechanism, and particularly a bond between radical polymerizable groups. Examples can include acrylic groups, methacrylic groups, maleimide groups, and organic groups containing any of these groups. Specific examples of the radical polymerizable group include groups such as acryloxypropyl, methacryloxypropyl, acrylamidopropyl, methacrylamidopropyl, 3-(N-maleimido)propyl, and the like. Examples of cationic polymerizable groups include vinyl ether groups, epoxy group-containing groups, oxetane group-containing groups, and other groups, such as CH₂═CH—O—(CH₂)ₙ— where n is an integer from 3 to 20), glycidyloxy —(CH₂)ₙ— where n is an integer from 3 to 20), 3,4-epoxycyclohexyl —(CH₂)ₙ— where n is an integer from 2 to 20), and the like.

One or more types of epoxy group-containing groups are preferred as the UV curable functional group. Examples of particularly preferable groups include glycidyloxypropyl groups, especially 3-glycidyloxypropyl groups, epoxycyclohexylalkyl groups, and particularly a 3,4-epoxycyclohexylethyl group.

In formula (3), R¹ to R⁸ other than the UV curable functional group are each independently an unsubstituted or fluorine-substituted monovalent hydrocarbon group, and preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, octyl, and other groups, and methyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups. The 3,3,3-trifluoropropyl group is preferred as the fluorine-substituted monovalent hydrocarbon group.

The number of UV curable functional groups provided by the organopolysiloxane of formula (3), serving as component (A) is, as a whole, 2 to 6 on average per molecule, preferably 2 to 5, more preferably 2 to 4, particularly preferably 2 to 3, and most preferably 2.

In particular, one of R₁ to R₃ in formula (3) and one of R₆ to Rs are preferably UV curable functional groups. Furthermore, one of R₁ to R₃ in formula (3) and one of R₆ to Rs are particularly preferably UV curable functional groups.

For n in formula (3), the viscosity of the organopolysiloxane expressed by formula (3) at 25° C. is preferably 1 to 1000 mPa·s, more preferably 1 to 500 mPa·s, particularly preferably 1 to 100 mPa·s, and most preferably 1 to 50 mPa·s. A person with ordinary skill in the art can easily determine the value of n without excess trial and error such that the viscosity of the organopolysiloxane of formula (3) is within the aforementioned viscosity range. In general, however, the number of silicon atoms per molecule is preferably 3 to 12, and particularly preferably between 3 to 5, in order for the compound of formula (3) to have the desired viscosity.

The organopolysiloxane of formula (3) can be used as one type or as a mixture of two or more types. If two or more organopolysiloxanes are used as a mixture, the viscosity of the mixture at 25° C. is preferably the viscosity described above.

Furthermore, the compound of formula (1) above may be an organopolysiloxane expressed by the following average unit formula (4.

Average unit formula:

(R₃SiO_{1/2})ₑ(R₂SiO_{2/2})_{f}(RSiO_{3/2})_{g}(SiO_{4/2})ₕ (4)

In formula (4), R independently represents a group selected from UV curable functional groups and unsubstituted or fluorine-substituted monovalent hydrocarbon groups, at least two of all Rs are UV curable functional groups, (g+h) is a positive number, e is 0 or a positive number, and f is a number within a range of 0 to 10.
The UV curable functional groups and monovalent hydrocarbon groups are as defined above for formula (1. Furthermore, a preferred viscosity of the organopolysiloxane expressed by formula (4) is as specified above for the organopolysiloxane expressed by formula (1.

The number of UV curable functional groups provided by the organopolysiloxane expressed by formula (4) is preferably 2 to 5, more preferably 2 to 4, particularly preferably 2 to 3, and most preferably 2, per molecule.

The organopolysiloxane expressed by formula (4) preferably has 3 to 20 silicon atoms per molecule, more preferably 3 to 12 atoms, and even more preferably 5 to 12 atoms.

Specific examples of the organopolysiloxanes expressed by (1) above, and particularly formula (3) or formula (4), include 1,5-bis[2-(3,4-epoxycyclohexyl)ethyl]-1,1,3,3,5,5-hexamethyltrisiloxane, 1,7-bis[2-(3,4-epoxycyclohexyl)ethyl]-1,1,3,3,5,5,7,7-octamethyltetrasiloxane, 1,9-bis[2-(3,4-epoxycyclohexyl)ethyl]-1,1,3,3,5,5,7,7,9,9-decamethylpentasiloxane, methyl(tris[2-(3,4-epoxycyclohexyl)ethyl]dimethylsiloxy)silane, tetrakis([2-(3,4-epoxycyclohexyl)ethyl]dimethylsiloxy)silane, 1,5-bis(3-glycidoxypropyl)-1,1,3,3,5,5-hexamethyltrisiloxane, 1,7-bis(3-glycidoxypropyl)-1,1,3,3,5,5,7,7-octamethyltetrasiloxane, 1,9-bis(3-glycidoxypropyl)-1,1,3,3,5,5,7,7,9,9-decamethylpentasiloxane, both-end terminated (3,4-epoxycyclohexylethyldimethylsilyl)-polydimethylsiloxane, both-end terminated (3-glycidoxypropyldimethylsilyl)-polydimethylsiloxane, both-end terminated trimethylsilyl-dimethylsiloxy/(methyl-3,4-epoxy) cyclohexylethylsiloxy) copolymer, both-end terminated trimethylsilyl-dimethylsiloxy/(methyl-3-glycidoxypropylsiloxy) copolymer, both-end terminated (3,4-epoxycyclohexylethyldimethylsilyl)-dimethylsiloxy/(methyl-3,4-epoxycyclohexylethylsiloxy) copolymer, and both-end terminated (3-glycidoxypropyldimethylsilyl)-dimethylsiloxy/(methyl-3-glycidoxypropylsiloxy) copolymer.

Furthermore, the compound of formula (1) above may be a cyclic organopolysiloxane expressed by the following formula (5):

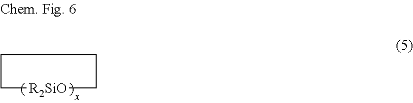

where R independently represents a group selected from UV curable functional groups and unsubstituted or fluorine-substituted monovalent hydrocarbon groups, x is an integer of 3 to 10, and at least two UV curable functional groups are present in a molecule.

The UV curable functional group and the unsubstituted or fluorine-substituted monovalent hydrocarbon group, which can be represented by R in Formula (5), are as defined for Formula (1) above.

Furthermore, a preferred viscosity of the organopolysiloxane expressed by formula (5) is as specified above for the organopolysiloxane expressed by formula (1.

Specific examples of the cyclic organopolysiloxane expressed by Formula (5) include 1,3,5-trimethyl-1,3,5-tri[2-(3, 4-epoxycyclohexyl)ethyl]cyclotrisiloxane, 1,3,5-trimethyl-1,3,5-tri(3-glycidoxypropyl)cyclotrisiloxane, 1,3,5,7-tetramethyl-1,3,5,7-tetra[2-(3,4-epoxycyclohexyl]ethyl] cyclotrisiloxane, 1,3,5,7-tetramethyl-1,3,5,7-tetra(3-glycidoxypropyl)cyclotetrasiloxane, 1,3,5,7,9-pentamethyl −1,3,5,7,9-penta[2-(3,4-epoxycyclohexyl)ethyl]cyclopentasiloxane, and 1,3,5,7,9-pentamethyl-1,3,5,7,9-penta(3-glycidoxypropyl)cyclopentasiloxane.

The organopolysiloxane expressed by formulas (1), (3) to (5) can each be individually one type, or optionally a combination of two or more types as component (A. Component (A) is particularly preferably one or more organopolysiloxane selected from the group consisting of the aforementioned organopolysiloxanes expressed by formula (3), cyclic organopolysiloxanes expressed by formula (5), and combinations thereof.

Component (A) is a linear organopolysiloxane having UV curable functional groups only at both ends of a molecular chain and an average number of silicon atoms in a range of 5 to 12, and particularly preferably a linear dimethylpolysiloxane having epoxy group-containing groups at both ends of the molecular chain.

A compound recommended as component (A) is one compound selected from a group consisting of 1,5-bis[2-(3,4-epoxycyclohexyl)ethyl]-1,1,3,3,5,5-hexamethyltrisiloxane, 1,9-bis[2-(3,4-epoxycyclohexyl)ethyl]-1,1,3,3,5,5,7,7,9,9-decamethylpentasiloxane, methyl(tris[2-(3,4-epoxycyclohexyl)ethyl]dimethylsiloxy)silane, tetrakis([2-(3,4-epoxycyclohexyl)ethyl]dimethylsiloxy)silane, both-end terminated (3,4-epoxycyclohexylethyldimethylsilyl)-polydimethylsiloxane, or a combination of two or more of the compounds. Of these, 1,1,3,3,5,5,7,7,9,9-decamethyl-1,9-bis[2-(3,4-epoxycyclohexyl)ethyl]pentasiloxane is particularly preferably used.

Component (B)

Component (B) is an organosilicon compound having one UV curable functional group in a molecule on an organosilane or organopolysiloxane backbone, and primarily has an effect of controlling crosslinking density of a cured product obtained from the composition of the present invention, adjusting the physical properties of the cured product, while simultaneously reducing the viscosity of the composition. Component (B) differs from component (A) in having only one UV curable functional group in a molecule. If two or more functional groups are present in a molecule, component (B) itself becomes a crosslinking component, and the objective of using the component may not be achieved.

On the other hand, the molecular structure of component (B) is arbitrary so long as the aforementioned objective can be achieved. As an example, an organosilicon compound of component (B) is an organosilane expressed by the following average compositional formula:

R_{c}R′_{d}SiO_{(4-c-d)/2} (2)

where R represents a UV curable functional group; R′ represents a group selected from monovalent hydrocarbon groups, hydroxyl groups, and alkoxy groups excluding the UV curable functional group; c and d are numbers that satisfy the following conditions: 1≤c+d≤4 and 0.05≤c/(c+d)≤0.25; and the number of R in a molecule is 1), or a linear, branched, or cyclic organopolysiloxane.
One selected from the group consisting of these organosilanes and organopolysiloxanes may be used, or any two or more may be used in combination.

The UV curable functional group represented by R in formula (2) is an organic group capable of generating a bond between each other by UV irradiation in the presence or absence of a photoinitiator. Examples of the UV curable functional groups can include radical polymerizable groups and cationic polymerizable groups. Radical polymerizable groups are not particularly limited so long as they are a functional group that can form a new bond by a radical reaction mechanism, and particularly a bond between radical polymerizable groups. Examples can include acrylic groups, methacrylic groups, maleimide groups, and organic groups containing any of these groups. Specific examples of the radical polymerizable group include groups such as acryloxypropyl, methacryloxypropyl, acrylamidopropyl, methacrylamidopropyl, 3-(N-maleimido)propyl, and the like. Examples of cationic polymerizable groups include vinyl ether groups, epoxy group-containing groups, oxetane group-containing groups, and other groups, such as CH₂═CH—O—(CH₂)ₙ— where n is an integer from 3 to 20), glycidyloxy —(CH₂)ₙ— where n is an integer from 3 to 20), 3,4-epoxycyclohexyl —(CH₂)ₙ— where n is an integer from 2 to 20), and the like.

One or more types of epoxy group-containing groups are preferred as the UV curable functional group. Examples of particularly preferable groups include glycidyloxypropyl groups, epoxycyclohexylalkyl groups, and particularly a 3,4-epoxycyclohexylethyl group. The organosilicon compound expressed by the aforementioned average compositional formula has one UV curable functional group (R) in a molecule.

The monovalent hydrocarbon group expressed by R′ of formula (2) independently represents a group selected from the group consisting of unsubstituted monovalent hydrocarbon groups and fluorine-substituted monovalent hydrocarbon groups. The unsubstituted or fluorine-substituted monovalent hydrocarbon group is preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, octyl, and other groups, and methyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups. The 3,3,3-trifluoropropyl group is preferred as the fluorine-substituted monovalent hydrocarbon group.

The viscosity of the organosilicon compound expressed by the aforementioned formula (2) at 25° C. is preferably 1 to 50 mPa·s, more preferably 1 to 20 mPa·s, and particularly preferably 2 to 10 mPa·s. The viscosity of the organosilicon compound can be adjusted by changing the ratio and the molecular weight of c and d in formula (2.

The organosilicon compound expressed by formula (2) is preferably a compound having 1 to 10, and preferably 1 to 4 silicon atoms per molecule.

In one preferred aspect, the organosiloxane or organopolysiloxane of component (A) is a compound expressed by the following formula (3′):

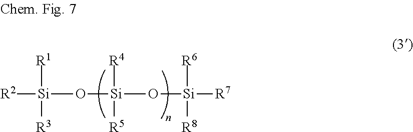

Similar to the compound expressed by formula (2) above, in the organopolysiloxane expressed by formula (3′), only one of all R¹ to R⁸ is a UV curable functional group.

Similar to the compound expressed by formula (2) above, the UV curable functional group is an organic group capable of generating a bond between each other by UV irradiation in the presence or absence of a photoinitiator. Examples of the UV curable functional groups can include radical polymerizable groups and cationic polymerizable groups. Radical polymerizable groups are not particularly limited so long as they are a functional group that can form a new bond by a radical reaction mechanism, and particularly a bond between radical polymerizable groups. Examples can include acrylic groups, methacrylic groups, maleimide groups, and organic groups containing any of these groups. Specific examples of the radical polymerizable group include groups such as acryloxypropyl, methacryloxypropyl, acrylamidopropyl, methacrylamidopropyl, 3-(N-maleimido)propyl, and the like. Examples of cationic polymerizable groups include vinyl ether groups, epoxy group-containing groups, oxetane group-containing groups, and other groups, such as CH₂═CH—O—(CH₂)ₙ— where n is an integer from 3 to 20), glycidyloxy —(CH₂)ₙ— where n is an integer from 3 to 20), 3,4-epoxycyclohexyl —(CH₂)ₙ— where n is an integer from 2 to 20), and the like.

One or more types of epoxy group-containing groups are preferred as the UV curable functional group. Examples of particularly preferable groups include glycidyloxypropyl groups, epoxycyclohexylalkyl groups, and particularly a 3,4-epoxycyclohexylethyl group.

In formula (3′), R₁ to R₈ other than the UV curable functional group are each independently an unsubstituted or fluorine-substituted monovalent hydrocarbon group, and preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, octyl, and other groups, and methyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups. The 3,3,3-trifluoropropyl group is preferred as the fluorine-substituted monovalent hydrocarbon group.

There is no limitation to the position of the UV curable functional group in the organopolysiloxane expressed by formula (3′), and a molecular end group, in other words, one of R₁ to R₃ or one of R₆ to Rs may be a UV curable functional group. Moreover, a non-end group, in other words, one of R₄ and R₅ in formula (3′) can be a UV curable functional group.

For n in formula (3′), the viscosity of the organopolysiloxane expressed by formula (3′) above at 25° C. is preferably 1 to 50 mPa·s, more preferably 1 to 20 mPa·s, and particularly preferably 2 to 10 mPa·s. A person with ordinary skill in the art can easily determine the value of n without excess trial and error such that the viscosity of the organopolysiloxane of formula (3′) is within the aforementioned viscosity range. In general, the number of silicon atoms per molecule is preferably 2 to 10, particularly preferably between 2 to 4, in order for the compound of formula (3′) to have the desired viscosity.

The organopolysiloxane of formula (3′) can be used as one type or as a mixture of two or more types. If a mixture of two or more organopolysiloxanes are used as a mixture, the viscosity of the mixture at 25° C. is 1 to 50 mPa·s, preferably 1 to 20 mPa·s, and more preferably 2 to 10 mPa·s.

Specific examples of organopolysiloxanes having one UV curable functional group per molecule expressed by Formula (3′) include 1-[2-(3,4-epoxycyclohexyl)ethyl]-1,1,3,3,3-pentamethyldisiloxane, 1-[2-(3,4-epoxycyclohexyl)ethyl]-1,1,3,3,5,5,5-heptamethyltrisiloxane, 3-[2-(3,4-epoxycyclohexyl)ethyl]-1,1,1,3,5,5,5-heptamethyltrisiloxane, and 1-[2-(3,4-epoxycyclohexyl)ethyl]-1,1,3,3,5,5,7,7,7-nonamethyltetrasiloxane, 1-(3-glycidoxypropyl)-1,1,3,3,3-pentamethyldisiloxane, 1-(3-glycidoxypropyl)-1,1,1,3,3,5,5,5-heptamethyltrisiloxane, 3-(3-glycidoxypropyl)-1,1,1,3,5,5,5-heptamethyltrisiloxane, and 1-(3-glycidoxypropyl)-1,1,3,3,5,5,7,7,7-nonamethyltetrasiloxane.

Furthermore, the aforementioned organosilicon compound of formula (2) above may be a cyclic organopolysiloxane expressed by the following formula (4′.

### Formula:

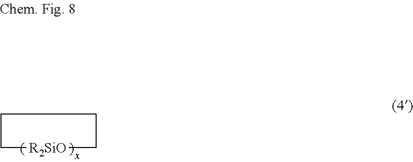

In formula (4′), R independently represents a group selected from UV curable functional groups and unsubstituted or fluorine-substituted monovalent hydrocarbon group, x is an integer of 3 to 5, and only one UV curable functional group is present in a molecule.

The UV curable functional groups and monovalent hydrocarbon groups are as defined above for the aforementioned formula (2.

A preferred viscosity of the cyclic organopolysiloxane expressed by formula (4′) is as specified above for the organopolysiloxane expressed by formula (2. Therefore, the viscosity at 25° C. is preferably 1 to 50 mPa·s, more preferably 1 to 10 mPa·s, and particularly preferably 2 to 10 mPa·s.

Specific examples of the cyclic organopolysiloxanes expressed by formula (4′) include [2-(3,4-epoxycyclohexyl)ethyl]-pentamethylcyclotrisiloxane, [2-(3,4-epoxycyclohexyl)ethyl]-heptamethylcyclotetrasiloxane, [2-(3,4-epoxycyclohexyl)ethyl]-nonamethylcyclopentasiloxane, 3-glycidoxypropyl-pentamethylcyclotrisiloxane, 3-glycidoxypropyl-heptamethylcyclotetrasiloxane, and 3-glycidoxypropyl-nonamethylcyclopentasiloxane.

Furthermore, component (B) may be an organosilane expressed by the following formula (5′.

Formula:

RSiR′₃ (5′)

In formula (5′), R represents a UV curable functional group, and R′ represents a group selected from monovalent hydrocarbon groups, hydroxyl groups, and alkoxy groups excluding the UV curable functional group.
The UV curable functional group and monovalent hydrocarbon group are as defined for the aforementioned formula (2) above, and alkoxy group is an alkoxy group with 1 to 20 carbon atoms, preferably 1 to 6 carbon atoms, and more preferably 1 to 3 carbon atoms, or a cycloalkyl group with 5 to 20 carbon atoms. Specifically, a methoxy group, ethoxy group, isopropoxy group, cyclopentyl group, or cyclohexyl group is preferred.

Furthermore, a preferred viscosity of the organosilane expressed by formula (5′) is the same as the aforementioned viscosity specified for the organopolysiloxane expressed by formula (2. Therefore, the viscosity at 25° C. is preferably 1 to 50 mPa·s, more preferably 1 to 20 mPa·s, and particularly preferably 2 to 10 mPa·s.

Specific examples of organosilanes expressed by formula (5′) include [2-(3,4-epoxycyclohexyl)ethyl]triethylsilane, [2-(3,4-epoxycyclohexyl)ethyl]dimethylphenylsilane, [2-(3,4-epoxycyclohexyl)ethyl]dimethyloctylsilane, [2-(3,4-epoxycyclohexyl)ethyl]dimethylcyclohexylsilane, [2-(3,4-epoxycyclohexyl)ethyl]trihexylsilane, [2-(3,4-epoxycyclohexyl)ethyl]tributylsilane, 3-glycidoxypropyltriethylsilane, 3-glycidoxypropyl dimethylphenylsilane, 3-glycidoxypropyl dimethyloctylsilane, 3-glycidoxypropyl dimethylcyclohexylsilane, 3-glycidoxypropyl trihexylsilane, and 3-glycidoxypropyl tributylsilane.

The organosilicon compounds expressed by formulas (2), (3′), (4′), and (5′) can be used individually or optionally in a combination of two or more types. In other words, the organosilicon compounds expressed by formula (2), (3′), (4′), or (5′), and mixtures of two or more compounds arbitrarily selected therefrom can be used as component (B) of the composition of the present invention.

As component (B), an organosilicon compound selected from organopolysiloxanes expressed by formula (3′), cyclic organopolysiloxanes expressed by formula (4′), and combinations thereof can be preferably used. In particular, component (B) is an organopolysiloxane having an average number of silicon atoms of three or more and having one UV curable functional group in a molecule, and the number of silicon atoms is particularly preferably 3 or 4.

Component (B) is particularly preferably 1,1,1,3,5,5,5-heptamethyl-3-[2-(3,4-epoxycyclohexyl)ethyl]trisiloxane.

Amount of component (A) and component (B) used

Components (A) and (B) can be used at an arbitrary mass ratio, but the ratio of component (A) is 25 mass % or more and 90 mass % or less, preferably 30% or more and 80 mass % or less, and even more preferably 40 mass % or more and 70% or less, with respect to the total amount of components (A) and (B) at 100 mass %. In other words, the ratio of component (B) is 10 mass % or more and 75 mass % or less, preferably 20 mass % or more and 70 mass % or less, and even more preferably 30 mass % or more and 60 mass % or less. When within this range, a material can be designed where the viscosity of the curable composition will be appropriate, and the mechanical properties of the resulting cured product, particularly tensile elongation, will be high.

On the other hand, from the perspective of suitably achieving the objective of the present invention, the amount of component (A) preferably exceeds 20 mass % of the total amount of the curable composition.

Component (A′)

In addition to the aforementioned components (A) and (B), one or more organopolysiloxanes (component A′) having two silicon atoms and having two UV curable functional groups in a molecule may be further added to the curable composition of the present invention. In particular, when an organopolysiloxane with more than 5 silicon atoms is used as component (A), the use of component (A′) may allow for the design of a material with high mechanical properties of a cured product, and particularly tensile elongation.

The UV curable functional groups of component (A′) can be the same as those listed in connection with components (A) and (B. Therefore, an organopolysiloxanes having two epoxy groups in a molecule, specifically a disiloxane having two epoxy groups in a molecule and two silicons can be used.

Specific examples of component (A′) can include 1,3-bis[2-(3,4-epoxycyclohexyl)ethyl]-1,1,3,3-tetramethyldisiloxane and 1,1-bis[2-(3,4-epoxycyclohexyl)ethyl]-1,3,3,3-tetramethyldisiloxane, but the 1,3-bis[2-(3,4-epoxycyclohexyl)ethyl]-1,1,3,3-tetramethyldisiloxane is preferred.

The viscosity of component (A′) is preferably 1 to 100 mPa·s, and more preferably 10 to 50 mPa·s at 25° C.

Component (A′) may be used to improve the mechanical properties, and particularly tensile elongation, of the cured product described above, and the added amount thereof may be adjusted to adjust the viscosity of the curable composition, improve the application properties, and adjust the physical properties of the cured product. Specifically, the amount of component (A′) in the curable composition of the present invention is preferably such that the mass ratio of component (A′) to the total of component (A), component (B), and component (A′) is less than 30%, in order to suppress a reduction in flexibility of the cured product. The mass ratio of component (A′) to the total of component (A), component (B), and component (A′) is preferably less than 25%, and even more preferably less than 20%.

Overall Viscosity of the Composition

The curable composition of the present invention can be used as a coating agent, the viscosity of the entire composition is 80 mPa·s or less at 25° C., as measured using an E-type viscometer, in order for the composition to have suitable flowability and workability for application to the substrate. The preferred viscosity range is 1 to 60 mPa·s, more preferably 5 to 30 mPa·s, and particularly preferably 5 to 20 mPa·s. The viscosity of the entire curable composition can be adjusted to the desired viscosity by using compounds with a preferred viscosity as each component so that the viscosity of the entire composition has the desired viscosity.

Organic Solvent-Free

The UV curable composition of the present invention can achieve a suitable viscosity for a coating agent without substantial use of an organic solvent by using each of the aforementioned components, the UV curable composition substantially does not include an organic solvent. In the present specification, the phrase “essential not containing an organic solvent” that the amount of organic solvents is less than 0.05 mass % of the total composition, preferably less than the analytical limit of analytical methods such as gas chromatography or the like. In the present invention, the desired viscosity can be achieved without the use of organic solvents by adjusting the molecular structure and molecular weight of component (A) and component (B.

Photopolymerization Initiator

In addition to the components (A) and (B) above, a photopolymerization initiator can be added to the UV curable composition of the present invention if desired. In this case, when the UV curable functional group provided by component (A) and component (B) is a cationic polymerizable functional group containing epoxy, vinylether, or the like, a photocationic polymerization initiator is used as the photopolymerization initiator. Well known photocationic polymerization initiators include compounds that can generate Brønsted acids or Lewis acids by UV or electron beam irradiation, and are so-called photoacid generators, and it is known that irradiation of ultraviolet rays or the like generates an acid, which causes a reaction between cationic polymerizable functional groups. Furthermore, when the UV curable functional group is a radical polymerizable functional group, a photoradical polymerization initiator can be used as the photopolymerization initiator. The photoradical polymerization initiator generates free radicals by irradiating ultraviolet rays or electron beams, which trigger a radical polymerization reaction, to cure the composition of the present invention. When the composition of the present invention is cured by electron beam irradiation, a polymerization initiator is normally not required.

(1) Photocationic Polymerization Initiator

The photocationic polymerization initiator used in the curable composition of the present invention can be selected from any known in the technical field and is not limited to any particular one. Strong acid generating compounds, such as diazonium salts, sulfonium salts, iodonium salts, phosphonium salts, and the like, are known as photocationic polymerization initiators, and these can be used. Examples of photocationic polymerization initiators include, but are not limited to, bis(4-tert-butylphenyl)iodonium hexafluorophosphate, cyclopropyldiphenylsulfonium tetrafluoroborate, dimethylphenacylsulfonium tetrafluoroborate, diphenyliodonium hexafluorophosphate, diphenyliodonium hexafluoroarsenate, diphenyliodonium tetrafluoromethanesulfonate, 2-(3,4-dimethoxystyryl)-4,6-bis(trichloromethyl)-1,3,5-triazine, 2-[2-(furan-2-yl)vinyl]-4,6-bis(trichloromethyl)-1,3,5-triazine, 4-isopropyl-4′-methyldiphenyliodonium tetrakis(pentafluorophenyl)borate, 2-[2-(5-methylfuran-2-yl)vinyl]-4,6-bis(trichloromethyl)-1,3,5-triazine, 2-(4-methoxyphenyl)-4,6-bis(trichloromethyl)-1,3,5-triazine, 2-(4-methoxystylyl)-4,6-bis(trichloromethyl)-1,3,5-triazine, 4-nitrobenzenediazonium tetrafluoroborate, triphenylsulfonium tetrafluoroborate, triphenylsulfonium bromide, tri-p-tolylsulfonium hexafluorophosphate, tri-p-tolylsulfonium trifluoromethanesulfonate, diphenyliodonium triflate, triphenylsulfonium triflate, diphenyliodonium nitrate, bis(4-tert-butylphenyl)iodonium perfluoro-1-butane sulfonate, bis(4-tert-butylphenyl)iodonium triflate, triphenylsulfonium perfluoro-1-butanesulfonate, N-hydroxynaphthalimide triflate, p-toluene sulfonate, diphenyliodonium p-toluenesulfonate, (4-tert-butylphenyl) diphenylsulfonium triflate, tris(4-tert-butylphenyl)sulfonium triflate, N-hydroxy-5-norbornene-2,3-dicarboxymide perfluoro-1-butanesulfonate, (4-phenylthiophenyl) diphenylsulfonium triflate, 4-(phenylthio) phenyldiphenylsulfonium triethyltrifluorophosphate, and the like. In addition to the aforementioned compounds, examples of the photocationic polymerization initiators can include commercially available photoinitiators such as Omnicat 250, Omnicat 270 (IGM Resins B.V.), CPI-310B, IK-1 (San-Apro Ltd.), DTS-200 (Midori Kagaku Co., Ltd.), Irgacure 290 (BASF), and the like.

The amount of the photocationic polymerization initiator added to the curable composition of the present invention is not particularly limited so long as a desired photocuring reaction occurs, but in general, the photocationic polymerization initiator is preferably used at an amount of 0.1 to 10 mass %, and preferably 0.2 to 5 mass %, and particularly preferably 0.5 to 4 mass % with respect to the total amount of components (A) and (B) of the present invention.

When the UV curable functional groups of components (A) and (B) are a photocationic polymerization initiator such as an epoxy group or the like, a photoradical polymerization initiator described below can be used in addition to the photocationic polymerization initiator described above as a polymerization initiator. The curability of the UV curable organopolysiloxane composition may be improved by using both initiators together.

(2) Photoradical Polymerization Initiator

The photo-radical polymerization initiators are known to be broadly classified into photo-fragmentation and hydrogen abstraction types. However, the photo-radical polymerization initiator used in the composition of the present invention can be selected arbitrarily from those known in the technical field, and is not limited to any particular one. Examples of photoradical polymerization initiators include, but are not limited to, acetophenone, p-anisyl, benzyl, benzoin, benzophenone, 2-benzoylbenzoic acid, 4,4′-bis(diethylamino)benzophenone, 4,4′-bis(dimethylamino) benzophenone, benzoin methyl ether, benzoin isopropyl ether, benzoin isobutyl ether, benzoin ethyl ether, 4-benzoylbenzoic acid, 2,2′-bis(2-chlorophenyl)-4,4′,5,5′-tetraphenyl-1,2′-biimidazole, methyl 2-benzoylbenzoate, 2-(1,3-benzodioxol-5-yl)-4,6-bis(trichloromethyl)-1,3,5-triazine, 2-benzyl-2-(dimethylamino)-4′-morpholinobutyrophenone, (±)-camphorquinone, 2-chlorothioxanthone, 4,4′-dichlorobenzophenone, 2,2-diethoxyacetophenone, 2,2-dimethoxy-2-phenylacetophenone, 2,4-diethylthioxanthene-9-one, diphenyl(2,4,6-trimethylbenzoyl)phosphine oxide, ethyl(2,4,6-trimethylbenzoyl)phenyl phosphinate, 1,4-dibenzoylbenzene, 2-ethylanthraquinone, 1-hydroxycyclohexylphenyl ketone, 2-hydroxy-2-methylpropiophenone, 2-hydroxy-4′-(2-hydroxyethoxy)-2-methylpropiophenone, 2-isopropylthioxanthone, lithium phenyl(2,4,6-trimethylbenzoyl)phosphinate, 2-methyl-4′-(methylthio)-2-morpholinopropiophenone, 2-isonitrosopropiophenone, 2-phenyl-2-(p-toluenesulfonyloxy)acetophenone, and phenylbis(2,4,6-trimethylbenzoyl)phosphine oxide, and the like. Furthermore, in addition to the aforementioned compounds, examples of the photoradical polymerization initiator can include initiators such as Omnirad (registered trademark) 651, 184, 1173, 2959, 127, 907, 369, 369E, and 379EG (alkylphenone photopolymerization initiators, IGM Resins B.V.), Omnirad (registered trademark) TPO H, TPO-L, and 819 (acylphosphine oxide photopolymerization initiators, IGM RESINS B.V.), Omnirad (registered trademark) MBF and 754 (intramolecular hydrogen abstraction-type photoinitiators, IGM Resins B.V.), Irgacure (registered trademark) OXE01 and OXE02 (oxime ester non-polymerization initiators, BASF), and the like.

While the amount of the photoradical polymerization initiator added to the composition of the present invention is not particularly limited so long as the intended photoradical polymerization reaction or photo-curing reaction occurs, it is generally used at an amount of 0.01 to 5 mass %, and preferably 0.05 to 1 mass % relative to the total mass of the composition of the present invention.

Moreover, a photosensitizer may be used in combination with the photocationic polymerization initiator or the photoradical polymerization initiator. Use of a sensitizer can increase the photon efficiency of the polymerization reaction, and is particularly effective when the coating thickness of the composition is relatively thick or when a relatively long-wavelength LED light source is used, because use of longer wavelength light for the polymerization reaction compared to only using a photoinitiator is feasible. While not limited thereto, examples of known sensitizers include anthracene based compounds, phenothiazine based compounds, perylene based compounds, cyanine based compounds, melocyanine based compounds, coumarin based compounds, benzylidene ketone based compounds, and (thio)xanthene or (thio)xanthone based compounds such as isopropylthioxanthone, 2,4-diethylthioxanthone, alkyl-substituted anthracenes, squarylium based compounds, (thia)pyrylium based compounds, porphyrin based compounds, and the like, with any photosensitizer capable of being used in the curable composition according to the present invention.

The cured product obtained from the curable composition of the present invention will have the desired properties of the cured product and the curing rate of the curable composition depending on the molecular chain length, position of the UV curable functional groups in a molecule, and molecular structure of component (A) and component (B) and the number of UV curable functional groups per molecule in component (A), and the viscosity of the cured composition can be designed to achieve the desired value. Furthermore, the cured product obtained by curing the curable composition of the present invention is also included in the scope of the present invention. Furthermore, the shape of the cured product obtained from the composition of the present invention is not particularly limited, and it may be a thin film coating layer, may be a sheet-like molded product or the like, may be injected into a specific site in an uncured state and then cured to form a filling material, or may be used as a sealing material for a laminated body, display device, or the like or as an intermediate layer. The cured product obtained from the composition of the present invention is particularly preferably in the form of a thin film coating layer, and is particularly preferably an insulating coating layer.

The curable composition of the present invention is suitably used as a coating agent or potting agent, in particularly an insulating coating agent or potting agent for an electronic or electrical device.

The cured product obtained by curing the curable composition of the present invention is characterized by excellent mechanical properties, and particularly tensile properties. When evaluated at a tensile speed of 50 mm/minute at 25° C. using a 0.5 mm thick test piece, the tensile elongation is usually 10% or more. By optimizing the curable composition, the tensile elongation of the cured product can be increased to 50% or more, and can be used as a layer forming material for a flexible display.

If desired, the cured product obtained by curing the curable composition of the present invention can be designed to have a dielectric constant of less than 3.0, or less than 2.8, or the like, and the curable composition of the present invention can also be used to form a coating layer having a low dielectric constant.

Component (C)

When the UV curable organopolysiloxane composition of the present invention is applied to a surface of a substrate as a coating agent using an arbitrary method, in order to improve the wettability of the composition on the substrate and to form a defect-free coating film, component (C) selected from the following can be further added to the composition of the present invention, containing the aforementioned components. The use of inkjet printing is particularly preferred as a method for coating the composition of the present invention on a substrate. Therefore, component (C) is a component that improves the wettability of the UV curable organopolysiloxane composition of the present invention on a substrate, and particularly significantly improves inkjet printing properties. Component (C) is at least one type of compound selected from a group consisting of the following (C1), (C2), and (C3.

(i) Component (C1)

Component (C1) is a nonionic surfactant that does not contain a silicon atom and is not acrylic, in other words, a nonacrylic nonionic surfactant. “Nonacrylic” means that the surfactant does not have a (meth)acrylate group in a molecule thereof. Examples of surfactants that can be used as component (C1) include glycerol fatty acid esters, sorbitan fatty acid esters, polyoxyethylene alkyl ethers, polyoxyethylene alkyl phenyl ethers, alkyl glycosides, acetylene glycol polyether, and other organic nonionic surfactants, fluorine-based nonionic surfactants, and the like, and one or a combination of two or more types thereof can be used. Specific examples of component (C1) include the EMULGEN Series and RHEODOL series manufactured by Kao Corporation, SURFYNOL 400 series manufactured by Evonik Industries AG, and OLFINE E series manufactured by Nissin Chemical Co., Ltd. as organic nonionic surfactants, and FC-4400 series manufactured by 3M and MEGAFACE 550 and 560 series manufactured by DIC Corporation as fluorine-based nonionic surfactants.
Of these, SURFYNOL400 series and OLFINE E series, which are alkynol polyethers, are particularly preferred.

(ii) Component (C2) is a nonionic surfactant containing a silicon atom and having an HLB value of 4 or less. Herein, the HLB value is a value that expresses the degree of affinity of a surfactant to water and organic compounds, and herein, a value defined by the Griffin method (20× sum of the formula weight of the hydrophilic portion/molecular weight) is used as the HLB value. Silicone polyether having a polyether as a hydrophilic portion, glycerol silicone having a (di)glycerol derivative as a hydrophilic portion, carbinol silicones having a hydroxyethoxy group as a hydrophilic portion, and the like are known silicon-containing nonionic surfactants. Of these surfactants, those with an HLB value of 4 or less, in other words, those with a hydrophilic portion mass fraction of 20 mass % or less, are preferably used in the composition of the present invention. Of these, carbinol silicone is particularly preferred.

(iii) Component (C3) is a silicone oil having a viscosity of 90 mPa·s or less at 25° C. Examples of silicone oils include both-end terminated trimethylsilyl-polydimethylsiloxane, both-end terminated dimethylvinylsilyl-polydimethylsiloxane, both-end terminated trimethylsilyl-dimethylsiloxy/methylvinylsiloxy copolymers, both-end terminated dimethylvinylsilyl-dimethylsiloxy/methylvinylsiloxy copolymers, both-end terminated trimethylsilyl-dimethylsiloxy/methylphenylsiloxy copolymers, both-end terminated trimethylsilyl-dimethylsiloxy/diphenylsiloxy copolymers, both-end terminated dimethylvinylsilyl-dimethylsiloxy/methylphenylsiloxy copolymers, both-end terminated dimethylvinylsilyl-dimethylsiloxy/diphenylsiloxy copolymers, and the like. Both-end terminated trimethylsilyl-polydimethylsiloxane and both-end terminated dimethylvinylsilyl-polydimethylsiloxane can be preferably used. A preferred viscosity range of the silicone oil is 2 to 50 mPa·s. A more preferred range is 2 to 30 mPa·s, and an even more preferred viscosity range is 5 to 20 mPa·s. Note that viscosity values herein were measured at 25° C. using a rotational viscometer described in the Examples.

Components (C1) through (C3) described above can be one or a combination of two or more thereof. The amount of component (C) in the curable composition is not particularly limited, but the total of components (C1) to (C3) (collectively referred to as component (C)) is preferably 0.05 mass % or more and 1 mass % or less relative to the total amount of 100 mass % of component (A) and component (B) described above. This is because if the amount of component (C) is less than 0.05 mass % relative to a total amount of 100 mass % of components (A) and (B), an effect of improving the wettability of the curable composition to a substrate may not be sufficient, and if the amount of component (C) exceeds 1 mass % relative to total amount of 100 mass % of components (A) and (B), there is a risk that component (C) may bleed out from a cured product after curing.

As component (C), a silicone oil of component (C3) is preferably used alone, or component (C3) is preferably used in combination with one or more components selected from a group consisting of component (C1) and component (C2. Component (C3) is preferably used alone as component (C.

Other Additives

Another additive may be added to the composition of the present invention if desired. Examples of additives that can be used include leveling agents, silane coupling agents not included in those listed above as adhesion imparting agents, UV absorbers, antioxidants, polymerization inhibitors, fillers (reinforcing fillers, insulating fillers, thermal conductive fillers, and other functional fillers), and the like. If necessary, an appropriate additive can be added to the composition of the present invention. Furthermore, a thixotropy imparting agent may also be added to the composition of the present invention if necessary, particularly when used as a potting agent or sealing agent. In particular, the following adhesion imparting agent may be and is preferably optionally added to the composition of the present invention.

Adhesion Imparting Agent

An adhesion promoter can be added to the composition of the present invention to improve adhesion and close fitting properties to a substrate in contact with the composition. When the curable composition of the present invention is used for applications such as coating agents, sealing materials, and the like that require adhesion or close fitting properties to a substrate, an adhesion imparting agent is preferably added to the curable composition of the present invention. An arbitrary known adhesion promoter can be used, so long as the adhesion promoter does not interfere with a curing reaction of the composition of the present invention.

Examples of such adhesion promoters that can be used in the present invention include: organosilanes having a trialkoxysiloxy group (such as a trimethoxysiloxy group or a triethoxysiloxy group) or a trialkoxysilylalkyl group (such as a trimethoxysilylethyl group or triethoxysilylethyl groups) and a hydrosilyl group or an alkenyl group (such as a vinyl group or an allyl group), or organosiloxane oligomers having a linear structure, branched structure, or cyclic structure with approximately 4 to 20 silicon atoms; organosilanes having a trialkoxysiloxy group or a trialkoxysilylalkyl group and a methacryloxyalkyl group (such as a 3-methacryloxypropyl group), or organosiloxane oligomers having a linear structure, branched structure, or cyclic structure with approximately 4 to 20 silicon atoms; organosilanes having a trialkoxysiloxy group or a trialkoxysilylalkyl group and an epoxy group-bonded alkyl group (such as a 3-glycidoxypropyl group, a 4-glycidoxybutyl group, a 2-(3,4-epoxycyclohexyl)ethyl group, or a 3-(3,4-epoxycyclohexyl)propyl group), or organosiloxane oligomers having a linear structure, branched structure, or cyclic structure with approximately 4 to 20 silicon atoms; organic compounds having two or more trialkoxysilyl groups (such as trimethylsilyl groups or triethoxysilyl groups); reaction products of aminoalkyltrialkoxysilane and epoxy group-bonded alkyltrialkoxysilane, and epoxide group-containing ethyl polysilicate. Specific examples thereof include vinyl trimethoxysilane, allyl trimethoxysilane, allyl triethoxysilane, hydrogen triethoxysilane, 3-glycidoxypropyl trimethoxysilane, 3-glycidoxypropyl triethoxysilane, 2-(3,4-epoxycyclohexyl)ethyl trimethoxysilane, 3-methacryloxypropyl trimethoxysilane, 3-methacryloxypropyl triethoxysilane, 1,6-bis(trimethoxysilyl)hexane, 1,6-bis(triethoxysilyl)hexane, 1,3-bis[2-(trimethoxysilyl)ethyl]-1,1,3,3-tetramethyldisiloxane, reaction products of 3-glycidoxypropyl triethoxysilane and 3-aminopropyl triethoxysilane, condensation reaction products of a methylvinyl siloxane oligomer blocked with a silanol group and a 3-glycidoxypropyl trimethoxysilane, condensation reaction products of a methylvinyl siloxane oligomer blocked with a silanol group and a 3-methacryloxypropyl triethoxysilane, tris(3-trimethoxysilylpropyl)isocyanurate.

The amount of the adhesion promoter to be added to the curable composition of the present invention is not particularly limited. However, since it does not promote curing properties of the curable composition or discoloration of a cured product, the amount is preferably within a range of 0.01 to 5 parts by mass, or within a range of 0.01 to 2 parts by mass, relative to a total of 100 parts by mass of components (A) and (B.

Application

The UV curable organopolysiloxane composition of the present invention can be cured not only by ultraviolet rays but also by electron beams, which is another aspect of the present invention.

The curable composition of the present invention has low viscosity, and is particularly useful as a material for forming an insulating layer for various articles, particularly electronic and electrical devices. The composition of the present invention can be applied on a substrate or sandwiched between two substrates, at least one of which includes a material that allows ultraviolet rays or electron beams to pass, and the composition can be cured by irradiating ultraviolet rays or electron beams to form an insulating layer. In this case, the composition of the present invention can be patterned when applied to a substrate, and then the composition can be cured. Alternatively, the composition can be applied to a substrate, and cured and uncured portions can be left during curing by ultraviolet rays or electron beam irradiation. Thereafter, an uncured portion can be removed with a solvent to form an insulating layer having a desired pattern. In particular, when the cured layer of the present invention is an insulating layer, the layer can be designed to have a low dielectric constant of less than 3.0.

The curable composition of the present invention provides favorable transparency of the cured product obtained therefrom, particularly suitable as a material for forming an insulating layer for touch panels and displays and other display devices. In this case, an arbitrary desired pattern may be formed as described above if necessary on the insulating layer. Therefore, a display device such as touch panel, display, or the like containing an insulating layer obtained by curing the UV curable organopolysiloxane composition of the present invention is also an aspect of the present invention.

Furthermore, the curable composition can also be used to form an insulating coating layer (insulating film) by curing after coating an article. Therefore, the composition of the present invention can be used as an insulating coating agent. Furthermore, a cured product formed by curing the curable composition of the present invention can be used as an insulating coating layer.

An insulating film formed from the curable composition of the present invention can be used for various applications. In particular, use is possible as a component of an electronic device or as a material used in a process of manufacturing the electronic device. Electronic devices include semiconductor devices, magnetic recording heads, and other electronic apparatuses. For example, the curable composition of the present invention can be used in an insulating film of a semiconductor device, such as an LSI, system LSI, DRAM, SDRAM, RDRAM, D-RDRAM, or a multi-chip module multilayer circuit board, an interlayer insulating film for a semiconductor, an etch stopper film, a surface protection film, a buffer coat film, a passivation film in LSI, a cover coat for a flexible copper cladding plate, a solder resistant film, and a surface protection film for an optical device.

Furthermore, the UV curable composition of the present invention can be used as a coating agent, or as a potting agent, and particularly as an insulating potting agent for electronic and electrical devices.

The composition of the present invention can be used as a material for forming a coating layer on a surface of a substrate, particularly using an inkjet printing method. In this case, the composition of the present invention particularly preferably contains component (C) described above.

The present invention is further described below based on Examples, but the present invention is not limited to the Examples below.

### EXAMPLES

The UV curable composition of the present invention and a cured product thereof of the present invention will be described below in further detail using examples. Furthermore, measurements and evaluations in the Examples and Comparative Examples were conducted as follows.

Viscosity of Curable Composition

The viscosity (mPa·s) of the composition at 25° C. was measured using a rotational viscometer (E-type viscometer VISCONIC EMD produced by TOKIMEC CORPORATION.

Appearance of curable composition and cured product obtained therefrom

The appearance of the curable composition and cured product obtained therefrom were observed and visually evaluated.

### Preparation of Curable Composition

Each material at the amounts listed in Table 1 below was placed in a brown plastic container and mixed well, using a planetary mixer to prepare the curable composition.

Curing of curable composition and preparation of tensile test piece

Approximately 0.2 g of curable composition was injected between two glass substrates with a 0.5 mm thick spacer interpose therebetween. By irradiating LED light having a wavelength of 405 nm at an energy intensity of 2 J/cm² from the outside through one glass substrate, the composition was cured to fabricate a plate-shaped cured product having a length of 50 mm and a thickness of 0.5 mm. The short pieces were trisected to fabricate 10×50×0.5 (thick) mm³ strip-shaped tensile samples

Wettability of curable organopolysiloxane composition on substrate (contact angle of composition)

Two microliters of the curable composition was dripped onto a silicon nitride coated glass substrate, and the contact angle of the curable composition immediately after dripping and after one minute was measured at 23° C. using a contact angle measuring device DM-700 manufactured by Kyowa Interface Science Co., Ltd. The unit for the contact angle is degrees (0.

### Examples and Comparative Examples

The UV curable compositions were prepared at the compositions (parts by mass) shown in Table 1 using each of the following components.
(A1) 1,1,3,3,5,5,7,7,9,9-decamethyl-1,9-bis[2-(3,4-epoxycyclohexyl)ethyl]pentasiloxane: Average number of silicon atoms of 5
(A2) Both-end [2-(3,4-epoxycyclohexyl)ethyl] substituted polydimethylsiloxane: Average number of silicon atoms of 12
(B) 1,1,1,3,5,5,5-heptamethyl-3-[2-(3,4-epoxycyclohexyl)ethyl]trisiloxane
(A) 1,3-bis[2-(3,4-epoxycyclohexyl)ethyl]-1,1,3,3-tetramethyldisiloxane
(C) DOWSILTM 5562 Carbinol Fluid (manufactured by The Dow Chemical Company)
(D1) 4-isopropyl-4′-methyldiphenyliodonium tetrakis(pentafluorophenyl)borate
(D2) 2-isopropylthioxanthone

TABLE 1

| | Example | Example | Example | Example | Example | Example | Comparative | Comparative |
|---|---|---|---|---|---|---|---|---|
| Component | 1 | 2 | 3 | 4 | 5 | 6 | Example 1 | Example 2 |
| (A1) | 66.30 | 49.16 | 29.58 | | | 49.06 | 99.46 | |
| (A2) | | | | 49.16 | 39.37 | | | 99.46 |
| (B1) | 33.16 | 50.30 | 69.88 | 50.30 | 40.51 | 50.18 | | |
| (A′) | | | | | 19.58 | | | |
| (C) | | | | | | 0.22 | | |
| (D1) | 0.50 | 0.50 | 0.50 | 0.50 | 0.50 | 0.50 | 0.50 | 0.50 |
| (D2) | 0.04 | 0.04 | 0.04 | 0.04 | 0.04 | 0.04 | 0.04 | 0.04 |
| Total | 100.0 | 100.0 | 100.0 | 100.0 | 100.0 | 100.0 | 100.0 | 99.9 |
| Mass ratio of A′ (%) | 0 | 0 | 0 | 0 | 19.58 | 0 | 0 | 0 |
| Appearance of curable | Trans- | Trans- | Trans- | Trans- | Trans- | Trans- | Trans- | Trans- |
| composition | parent | parent | parent | parent | parent | parent | parent | parent |
| Appearance of cured | Trans- | Trans- | Trans- | Trans- | Trans- | Trans- | Trans- | Trans- |
| product | parent | parent | parent | parent | parent | parent | parent | parent |
| Viscosity of composition | 18 | 13 | 10 | 14 | 19 | 13 | 23 | 27 |
| Contact angle of | | 14 | | | | 14 | | |
| composition: | | | | | | | | |
| Immediately after | | | | | | | | |
| dripping (°) | | | | | | | | |
| Contact angle of | | 8 | | | | 7 | | |
| composition: 1 minute | | | | | | | | |
| after dripping (°) | | | | | | | | |
| Tensile elongation | 15 | 53 | 38 | 28 | 50 | 53 | ≤10 | ≤10 |
| of cured product (%) | | | | | | | | |

As shown in Table 1, the UV curable compositions of the present invention (Examples 1 to 6) have viscosities at 25° C. that are suitable for application onto substrates as coating agents, particularly by inkjet printing. Furthermore, the composition has favorable wettability to the substrate, but the addition of component (C) can further improve the wettability (Example 6. Furthermore, the cured product obtained from the composition of the present invention has high tensile elongation and excellent flexibility. On the other hand, in the compositions not containing component (B) (Comparative Examples 1 and 2), the viscosity is low enough to enable application, but the tensile elongation of cured products is low. Thus, it is difficult to say that the cured products have sufficient flexibility.

### INDUSTRIAL APPLICABILITY

The UV curable composition of the present invention is particularly suitable for the applications described above, and particularly as a material for forming an insulating layer for touch panels and displays and other display devices, and particularly flexible displays.

1. A UV curable composition, comprising:
(A) one or more organopolysiloxane with three or more silicon atoms and having, on average, two or more UV curable functional groups in a molecule; and
(B) one or more organosilicon compound having one UV curable functional group in a molecule;
wherein the composition is substantially free or an organic solvent, and the viscosity of the Composition measured at 25° C. using an E-type viscometer is 80 mPa·s or less.

2. The UV curable composition according to claim 1, wherein the number of silicon atoms in component (A) is, on average, in a range of 3 to 12.

3. The UV curable composition according to claim 1, wherein component (A) is a linear, branched or cyclic organopolysiloxane expressed by the average compositional formula:
RₐR′_{b}SiO_{(4-a-b)/2} (1)
where R represents a UV curable functional group;
R′ represents a group selected from monovalent hydrocarbon groups, hydroxyl groups, and alkoxy groups excluding the UV curable functional group; and
a and b are numbers that satisfy the following conditions: 1≤(a+b)≤3 and 0.01≤(a/(a+b))≤0.5, and at least two Rs are present in a molecule.

4. The UV curable composition according to claim 3, wherein component (A) is at least one type of organopolysiloxane having a UV curable functional group, selected from a group consisting of: organopolysiloxanes expressed by the following formula (3): 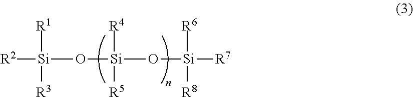
where two or more, on average, of all R¹ to R⁸ groups per molecule are UV curable functional groups; other R¹ to R⁸ independently represent an unsubstituted or fluorine-substituted monovalent hydrocarbon group; and n is a number of 1 or more and 20 or less;
organopolysiloxanes expressed by the average unit formula:
(R₃SiO_{1/2})ₑ(R₂SiO_{2/2})_{f}(RSiO_{3/2})_{g}(SiO_{4/2})ₕ (4)
where R independently represents a group selected from UV curable functional groups and unsubstituted or fluorine-substituted monovalent hydrocarbon groups, at least two of all Rs are UV curable functional groups, (g+h) is a positive number, e is 0 or a positive number, and f is a number within a range of 0 to 10;
cyclic organopolysiloxanes expressed by the following formula (5): 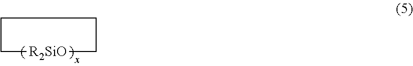
where R independently represents a group selected from UV curable functional groups and unsubstituted or fluorine-substituted monovalent hydrocarbon groups, x is an integer of 3 to 10, and at least two UV curable functional groups are present in a molecule); and
mixtures of two or more organopolysiloxane optionally selected therefrom.

5. The UV curable composition according to claim 1, wherein the number of UV curable functional groups in component (A) is, on average, two per molecule.

6. The UV curable composition according to claim 1, wherein component (A) is a linear organopolysiloxane having UV curable functional groups only on both ends of a molecular chain and having, on average, 5 to 12 silicon atoms.

7. The UV curable composition according to claim 1, wherein component (B) is an organosilicon compound selected from a group consisting of linear, branched, and cyclic organosilanes and organopolysiloxanes expressed by the average compositional formula:
R_{c}R′_{d}SiO_{(4-c-d)/2} (2)
where R represents a UV curable functional group;
R′ represents a group selected from monovalent hydrocarbon groups, hydroxyl groups, and alkoxy groups excluding the UV curable functional group;
c and d are numbers that satisfy the following conditions: 1<(c+d)≤4 and 0.05≤(c/(c+d))≤0.25, and the number of R in the molecule is 1.

8. The UV curable composition according to claim 7, wherein component (B) is a silicon-containing compound containing one UV curable functional group in a molecule, the silicon-containing compound selected from a group consisting of:
organopolysiloxanes expressed by the following formula (3′): 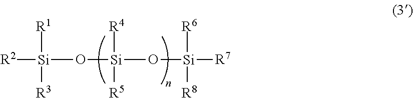
where of all R¹ to R⁸ groups, only one UV curable functional group is present in a molecule; the other groups of R¹ to R⁸ independently represent an unsubstituted or fluorine-substituted monovalent hydrocarbon group; and n is a numerical value of 0 or more and 3 or less;
cyclic organopolysiloxanes expressed by the following formula (4′): 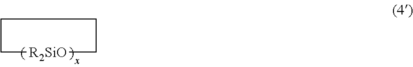
where R independently represents a group selected from UV curable functional groups and unsubstituted or fluorine-substituted monovalent hydrocarbon groups, x is an integer of 3 to 5, and only one UV curable functional group is present in a molecule); and
organosilanes expressed by the following formula (5′):
RSiR′₃ (5′)
where R represents a UV curable functional group, and R′ represents a group selected from monovalent hydrocarbon groups, hydroxyl groups, and alkoxy groups excluding the UV curable functional group.

9. The UV curable composition according to claim 1, wherein component (B) is an organopolysiloxane having, on average, three or more silicon atoms and having one UV curable functional group in a molecule.

10. The UV curable composition according to claim 1, wherein component (A) and component (B) are included in the UV curable composition at a mass ratio of 25/75 to 90/10 (A/B.

11. The UV curable composition according to claim 1, wherein the amount of component (A) in the UV curable composition exceeds 20 mass % with respect to the total amount of the curable composition.

12. The UV curable composition according to claim 1, further comprising at least one (A′) organopolysiloxane having two silicon atoms and having two UV curable functional groups in a molecule at an amount such that the mass ratio of component (A′) with respect to the total amount of component (A), component (B) and component (A′) is less than 30%.

13. The UV curable composition according to claim 1, wherein the UV curable functional group is a cationic polymerizable functional group.

14. The UV curable composition according to claim 1, wherein the UV curable functional group is an epoxy group-containing group.

15. The UV curable composition according to claim 1, wherein component (A) is 1,1,3,3,5,5,7,7,9,9-decamethyl-1,9-bis[2-(3,4-epoxycyclohexyl)ethyl]pentasiloxane.

16. The UV curable composition according to claim 1, wherein component (B) is 1,1,1,3,5,5,5-heptamethyl-3-[2-(3,4-epoxycyclohexyl)ethyl]trisiloxane.

17. The UV curable composition according to claim 1, wherein the viscosity of the composition measured at 25° C. using an E-type viscometer is 5 to 30 mPa·s.

18. An insulating coating agent, comprising: the UV curable composition according to claim 1.

19. A cured product of the UV curable composition according to claim 1, and optionally wherein a display device comprises a layer containing the cured product.

20. A method of using an insulating coating layer of a cured product of the UV curable composition according to claim 1.

21. (canceled)
